(19) United States
(12) Patent Application Publication
(10) Pub. No.: US 2023/0214551 A1
(43) Pub. Date: Jul. 6, 2023

(54) VIRTUAL DRIVING SYSTEM AND ITS CONTROL METHOD

(71) Applicant: SEMES CO., LTD., Chungcheongnam-do (KR)

(72) Inventors: Seung Wan AN, Gyeonggi-do (KR); Hyun Joon YOON, Gyeonggi-do (KR); Hyun Seong MOON, Gyeonggi-do (KR); Jae Uk KIM, Seoul (KR); Min Gi CHOI, Incheon (KR)

(21) Appl. No.: 17/978,973

(22) Filed: Nov. 2, 2022

(30) Foreign Application Priority Data
Dec. 30, 2021 (KR) 10-2021-0193039
Feb. 7, 2022 (KR) 10-2022-0015232

(51) Int. Cl. G06F 30/20; G06F 30/13; G01M 13/00

(52) U.S. Cl. CPC G06F 30/20; G06F 30/13; G01M 13/00; B66C 7/08

(57) ABSTRACT

A virtual driving system for efficiently testing an interlock operation is provided. The virtual driving system comprises an optical cable installed on a rail; a transport cart for driving in place on the rail and communicating with the optical cable; a first collision avoidance control unit set to correspond to a first virtual path of the transport cart; a second collision avoidance control unit set to correspond to a second virtual path different from the first virtual path of the transport cart; a signal line distribution unit for selectively connecting any one of the first collision avoidance control unit and the second collision avoidance control unit to the optical cable; and a simulator for controlling the first collision avoidance control unit, the second collision avoidance control unit, and the signal line distribution unit according to an operation scenario of the transport cart.

This application claims the benefit of Korean Patent Application No. 10-2021-0193039 filed on Dec. 30, 2021, and Korean Patent Application 10-2022-0015232 filed on Feb. 7, 2022, in the Korean Intellectual Property Office, the disclosure of which is incorporated herein by reference in its entirety.

### BACKGROUND

### 1. Field

The present invention relates to a virtual driving system and a method for controlling the same.

### 2. Description of the Related Art

Within a semiconductor factory, transported goods (e.g., Front Opening Universal Pod (FOUP), Front Opening Shipping Box (FOSB)) are moved by an automatic transport system. In the automatic transport system, for example, a transport cart such as an overhead hoist transport (OHT), an overhead shuttle (OHS), etc. may be used.

### SUMMARY

On the other hand, in the automatic transport system, a plurality of transport carts move simultaneously along the rail. There is a possibility that some transport carts collide with each other, for example, at the junction of rails. Therefore, if the normal operation (i.e., the transport carts enter the junction sequentially one by one) does not occur at the junction of the rails, and an abnormal operation (i.e., two transport carts enter the junction at the same time) occurs, the transport cart is interlocked.

A virtual driving system can be used to test the operation of the transport cart. It is necessary to efficiently test the above-described interlock operation in a virtual driving system.

An object of the present invention is to provide a virtual driving system for efficiently testing an interlock operation.

Another object of the present invention is to provide a control method of a virtual driving system for efficiently testing an interlock operation.

The objects of the present invention are not limited to the objects mentioned above, and other objects not mentioned will be clearly understood by those skilled in the art from the following description.

One aspect of the virtual driving system of the present invention for achieving the above object comprises an optical cable installed on a rail; a transport cart for driving in place on the rail and communicating with the optical cable; a first collision avoidance control unit set to correspond to a first virtual path of the transport cart; a second collision avoidance control unit set to correspond to a second virtual path different from the first virtual path of the transport cart; a signal line distribution unit for selectively connecting any one of the first collision avoidance control unit and the second collision avoidance control unit to the optical cable; and a simulator for controlling the first collision avoidance control unit, the second collision avoidance control unit, and the signal line distribution unit according to an operation scenario of the transport cart.

Other aspect of the virtual driving system of the present invention for achieving the above other object comprises a rail; a first optical cable disposed on one side of the rail and a second optical cable disposed on the other side of the rail; a transport cart for driving in place on the rail and communicating with at least one of the first optical cable and the second optical cable; a signal line distribution unit including a first node connected to the first optical cable, a plurality of first distribution ports, a first switch selectively connecting any one of the plurality of first distribution ports and the first node, a second node connected to the second optical cable, a plurality of second distribution ports, and a second switch selectively connecting any one of the plurality of second distribution ports and the second node; a first collision avoidance control unit including a first control port and a second control port; a second collision avoidance control unit including a third control port and a fourth control port; and a simulator for controlling the first collision avoidance control unit, the second collision avoidance control unit, and the signal line distribution unit; wherein the first control port is connected to any one of the plurality of first distribution ports, wherein the second control port is connected to any one of the plurality of second distribution ports, the third control port is connected to the other one of the plurality of second distribution ports, and the fourth control port is connected to another one of the plurality of second distribution ports, wherein the simulator changes a connection relationship between the first switch and the second switch according to an operation scenario of the transport cart.

One aspect of the method for controlling the virtual driving system of the present invention for achieving the above object comprises providing a virtual driving system including an optical cable installed on a rail, a transport cart for driving in place on the rail and communicating with the optical cable, and a signal line distribution unit for selectively connecting any one of a first collision avoidance control unit and a second collision avoidance control unit to the optical cable, setting the first collision avoidance control unit to correspond to a first virtual path of the transport cart, setting the second collision avoidance control unit to correspond to a second virtual path different from the first virtual path of the transport cart, wherein the signal line distribution unit connects the first collision avoidance control unit and the optical cable to simulate the transport cart to move along the first virtual path, wherein the signal line distribution unit connects the second collision avoidance control unit and the optical cable to simulate moving the transport cart along the second virtual path.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a block diagram for describing a virtual driving system according to some embodiments of the present invention;

FIG. 2 is a block diagram illustrating a virtual driving system according to an embodiment of the present invention;

FIG. 3 is a diagram for describing an example of a virtual path;

FIG. 4 is a view for describing a control method of a virtual driving system for testing the operation of the transport cart moving along the virtual path shown in FIG. 3;

FIG. 5 is a diagram for describing another example of a virtual path;

FIG. 6 is a view for describing a control method of a virtual driving system for testing the operation of the transport cart moving along the virtual path shown in FIG. 5;

FIG. 7 is a diagram for describing another example of a virtual path;

FIG. 8 is a view for describing a control method of a virtual driving system for testing the operation of the transport cart moving along the virtual path shown in FIG. 7; and

FIG. 9 is a flowchart illustrating a control method of a collision avoidance system according to some embodiments of the present invention.

### DETAILED DESCRIPTION

Hereinafter, preferred embodiments of the present invention will be described in detail with reference to the accompanying drawings. Advantages and features of the present invention and methods of achieving them will become apparent with reference to the embodiments described below in detail in conjunction with the accompanying drawings. However, the present invention is not limited to the embodiments described below, but may be implemented in various different forms, and these embodiments are provided to make the description of the present invention complete, and fully inform those skilled in the art, to which the present invention pertains on the scope of the invention, and the present invention is only defined by the scope of the claims. Like reference numerals refer to like elements throughout.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present disclosure.

Hereinafter, embodiments of the present disclosure will be described in detail with reference to the accompanying drawings, and in the description with reference to the accompanying drawings, the same or corresponding components are given the same reference numbers, regardless of reference numerals in drawings, and an overlapped description therewith will be omitted.

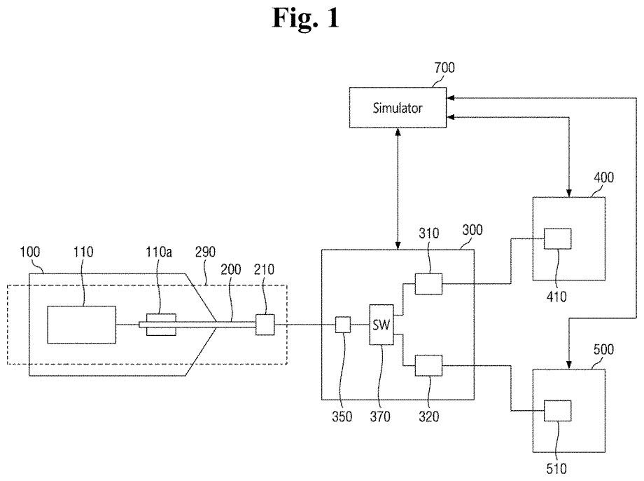

FIG. 1 is a block diagram for describing a virtual driving system according to some embodiments of the present invention.

Referring to FIG. 1, a virtual driving system according to some embodiments of the present invention includes a transport cart 100, an optical cable 200, a signal line distribution unit (MUX) 300, a first collision avoidance control unit 400, a second collision avoidance control unit 500 and a simulator 700.

The transport cart 100 may be, for example, an overhead hoist transport (OHT) or an overhead shuttle (OHS). The transport cart 100 is driven in place on the rail 290. For example, as the traveling wheel of the transport cart 100 rotates on the traveling-corresponding wheel of the rail 290, the transport cart 100 may be driven in place.

The rail 290 may be installed to a length required for the transport cart 100 to be driven in place.

The optical cable 200 may be installed along the rail 290. The optical cable 200 includes at least one light generating unit, and generates light by receiving power. For example, a line connecting the optical cable 200 and the signal line distribution unit 300 and a line connecting the signal line distribution unit 300 and the first/second collision avoidance control units 400 and 500 may be a line that can provide not only a signal but also power. FIG. 1 shows that one optical cable 200 is installed on the rail 290, but is not limited thereto. Two or more optical cables 200 may be installed on the rail 290.

The transport cart 100 may include a transceiver unit 110a and a control unit 110.

The transceiver unit 110a may communicate with the optical cable 200. The transceiver unit 110a may receive a signal (e.g., an exception signal) provided from the first collision avoidance control unit 400 or the second collision avoidance control unit 500 through the optical cable 200. In addition, a signal (e.g., a signal indicating the state of the transport cart 100) generated by the transport cart 100 may be transmitted through the optical cable 200 to the first collision avoidance control unit 400 or the second collision avoidance control unit 500.

The control unit 110 may interpret the signal received through the transceiver unit 110a and perform an operation corresponding thereto. For example, when the first collision avoidance control unit 400 or the second collision avoidance control unit 500 provides an exception signal, the control unit 110 may interlock the transport cart 100 accordingly. Also, the control unit 110 may generate an interlock state signal (i.e., a signal indicating interlock success or interlock failure) and provide it to the transceiver unit 110a.

A transceiver unit 210 is installed on one side of the optical cable 200. Through the transceiver unit 210, a signal (e.g., an exception signal) is received from the signal line distribution unit 300, or a signal (e.g., an interlock state signal) is transmitted to the signal line distribution unit 300.

The signal line distribution unit 300 is disposed between the optical cable 200 (i.e., the transceiver unit 210) and the first/second collision avoidance control units 400 and 500. The signal line distribution unit 300 selectively connects any one of the first collision avoidance control unit 400 and the second collision avoidance control unit 500 to the optical cable 200.

Specifically, the signal line distribution unit 300 includes a node 350 connected to the optical cable 200, a plurality of distribution ports 310 and 320, and a switch 370 for connecting any one of the plurality of distribution ports 310 and 320 to the node 350. Here, the first distribution port 310 of the plurality of distribution ports 310 and 320 is connected to the control port 410 of the first collision avoidance control unit 400, and the second distribution port 320 is connected to the control port 510 of the second collision avoidance control unit 500.

The first collision avoidance control unit 400 or the second collision avoidance control unit 500 is connected to the optical cable 200 through the signal line distribution unit 300, and a signal (or command) may be provided to the transport cart 100 through the optical cable 200, or a signal may be provided from the transport cart 100. As described above, the first collision avoidance control unit 400 or the second collision avoidance control unit 500 may provide an exception signal (i.e., an interlock signal) to the transport cart 100, and an interlock state signal may be provided from the transport cart 100.

Also, the first collision avoidance control unit 400 may be set to correspond to the first virtual path of the transport cart 100 under the control of the simulator 700. In other words, the first collision avoidance control unit 400 is set to the first mode.

The second collision avoidance control unit 500 may be set to correspond to a second virtual path different from the first virtual path of the transport cart 100 under the control of the simulator 700. In other words, the second collision avoidance control unit 500 is set to a second mode different from the first mode.

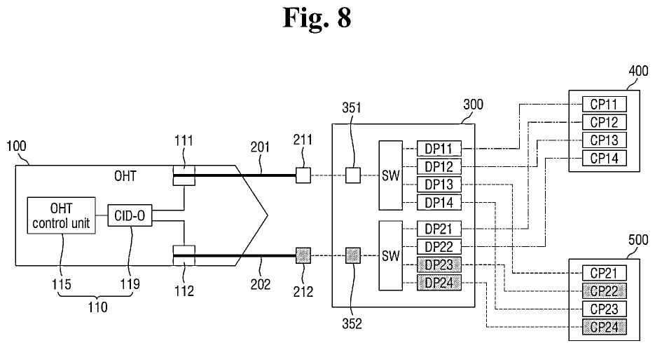

For example, the first virtual path may include a junction of rails, and the second virtual path may include a ramp, but is not limited thereto. An example of a junction of the rail will be described later with reference to FIGS. 3 to 6, and an example of a ramp will be described later with reference to FIGS. 7 and 8.

As described above, the signal line distribution unit 300 may selectively connect the optical cable 200 to any one of the first collision avoidance control unit 400 and the second collision avoidance control unit 500. The reason for doing this is as follows.

If the setting of one collision avoidance control unit (e.g., 400) is used as the first mode, the virtual driving test may be performed while changing to the second mode. However, since a predetermined mode change time is required for the collision avoidance control unit (e.g., 400) to change the mode, a delay occurs.

On the other hand, in the virtual driving system according to some embodiments of the present invention, the simulator 700 presets the modes of the plurality of collision avoidance control units 400 and 500 to suit the driving environment. And, according to the operation scenario of the transport cart 100, the simulator 700 connects the collision avoidance control unit 400 or 500 to be used to the optical cable 200 using the signal line distribution unit 300. Therefore, mode change time and delay are not generated. It is possible to quickly and accurately perform a virtual driving test of the transport cart 100.

In addition, the simulator 700 may adjust the size of power transmitted to the optical cable 200. When the size of the power decreases, the brightness of the light of the optical cable 200 may become dark, and when the size of the power increases, the brightness of the light of the optical cable 200 may become bright. The simulator 700 controls the brightness of the light in this way, and checks the operation of the transport cart 100 according to the brightness. In the mass production line, the distance between the transport cart 100 and the rail 290 may vary, and accordingly, the brightness of the light of the optical cable 200 recognized by the transport cart 100 may also vary. While changing the brightness of the optical cable 200 by adjusting the size of power, it is possible to test whether the transport cart 100 can recognize this.

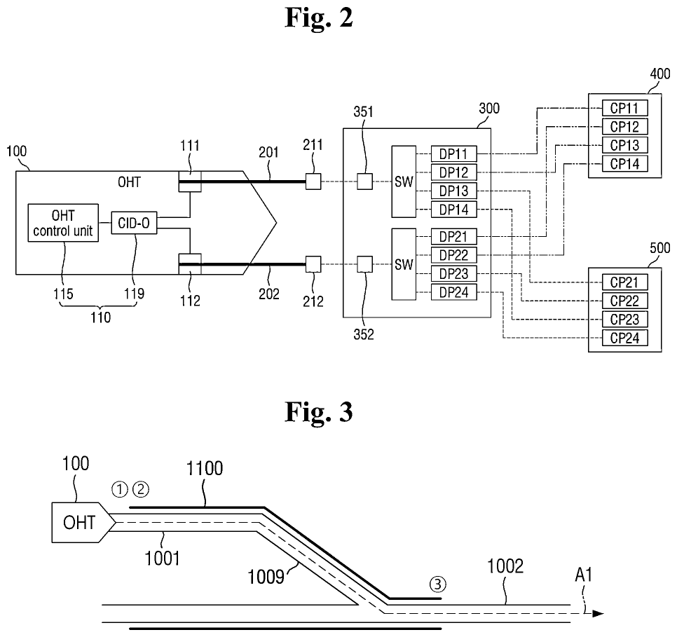

FIG. 2 is a block diagram illustrating a virtual driving system according to an embodiment of the present invention. FIG. 2 is a specific example of the virtual driving system shown in FIG. 1. Contents substantially the same as those described with reference to FIG. 1 will be omitted.

Referring to FIG. 2, in the virtual driving system according to an embodiment of the present invention, a first optical cable 201 is installed on one side (e.g., the left side) of the rail, and a second optical cable 202 is installed on the other side (e.g., the right side) of the rail.

The transport cart 100 includes a first transceiver unit 111, a second transceiver unit 112, an I/O signal generation unit 119, and a transport device control unit 115. The I/O signal generation unit 119 and the transport device control unit 115 correspond to the control unit 110 of FIG. 1, and the first transceiver unit 111 and the second transceiver unit 112 correspond to the transceiver unit 110a of FIG. 1.

The first transceiver unit 111 may correspond to the first optical cable 201 and communicate with the first optical cable 201. The second transceiver unit 112 may correspond to the second optical cable 202 and communicate with the second optical cable 202. The I/O signal generation unit 119 generates an I/O signal based on the signals received by the first transceiver unit 111 and the second transceiver unit 112. The transport device control unit 115 interprets the I/O signal and performs an operation corresponding thereto. For example, the transport device control unit 115 may interlock the transport cart 100.

A first transceiver unit 211 is installed at one end of the first optical cable 201, and a second transceiver unit 212 is installed at one end of the second optical cable 202.

The signal line distribution unit 300 includes a first node 351, a plurality of first distribution ports DP11, DP12, DP13, DP14, a first switch 371, a second node 352, a plurality of second distribution ports DP21, DP22, DP23, DP24, and a second switch 372.

The first node 351 is connected to the first optical cable 201 (or the first transceiver unit 211). Some (DP11, DP12) of the plurality of first distribution ports (DP11, DP12, DP13, DP14) are connected to some first control ports (CP11, CP13) of the first collision avoidance control unit 400, and the other part (DP13, DP14) are connected to some second control ports (CP21, CP23) of the second collision avoidance control unit 500. The first switch 371 selectively connects the first node 351 to any one of the plurality of first distribution ports DP11, DP12, DP13, and DP14. As a result, the first node 351 is connected to any one of the first control ports CP11 and CP13 and the second control ports CP21 and CP23 by the first switch 371.

The second node 352 is connected to the second optical cable 202 (or the second transceiver unit 212). Some (DP21, DP 22) of the plurality of second distribution ports (DP21, DP22, DP23, DP24) are connected to some first control ports (CP12, CP14) of the first collision avoidance control unit 400, and the other part (DP23, DP24) are connected to some second control ports (CP22, CP24) of the second collision avoidance control unit 500. The second switch 372 selectively connects the second node 352 to any one of the plurality of second distribution ports DP21, DP22, DP23, and DP24. As a result, the second node 352 is connected to any one of the first control ports CP12 and CP14 and the second control ports CP22 and CP24 by the second switch 372.

The operations of the first switch 371 and the second switch 372 are determined by the simulator 700 according to the operation scenario of the transport cart 100.

Hereinafter, a control method of the virtual driving system will be described in detail with reference to FIGS. 3 to 8.

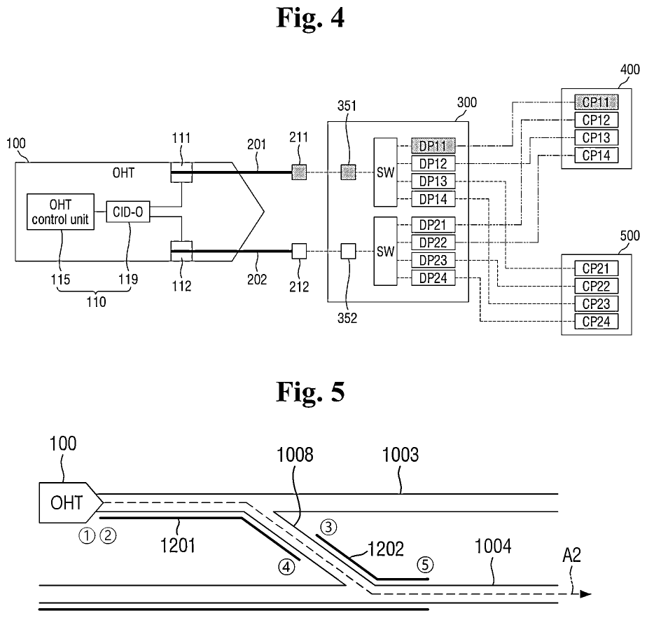

FIG. 3 is a diagram for describing an example of a virtual path. FIG. 4 is a view for describing a control method of a virtual driving system for testing the operation of the transport cart moving along the virtual path shown in FIG. 3.

The virtual path A1 shown in FIG. 3 includes a path at the junction of the rails. Specifically, the junction of the rail is a form, in which the first rail 1001 and the second rail 1002 are joined. Specifically, the first rail 1001 and the second rail 1002 are parallel to each other, and the connection rail 1009 extends from the end of the first rail 1001 toward the second rail 1002. As shown, the first virtual optical cable 1100 is installed on one side (e.g., the left side) of the first rail 1001 and the connection rail 1009, and extends to one side of the second rail 1002 (e.g., the left side).

In the virtual path A1 of the transport cart 100, the transport cart 100 moves along the first rail 1001 and moves to the second rail 1002 through the connection rail 1009.

Referring to FIGS. 3 and 4, when the virtual driving starts and the transport cart 100 is at the position \textcircled{1} of the first rail 1001, a channel for communication between the transport cart 100 and the first collision avoidance control unit 400 is established. In addition, the simulator 700 controls the signal line distribution unit 300 and the first collision avoidance control unit 400 to set to correspond to the virtual path A1 shown in FIG. 3.

Specifically, the simulator (see 700 in FIG. 1) allows the signal line distribution unit 300 to connect the first collision avoidance control unit 400 and the first optical cable 201 to each other. Specifically, the first node 351 is connected to the first distribution port DP11 by the first switch 371. Accordingly, the first optical cable 201 is connected to the first control port CP11 of the first collision avoidance control unit 400 through the first node 351 and the first distribution port DP11.

The simulator 700 gives an ID corresponding to the first virtual optical cable 1100 of FIG. 3 through the first control port CP11 of the first collision avoidance control unit 400. Accordingly, the transport cart 100 recognizes the ID of the first virtual optical cable 1100.

When the transport cart 100 is at the position \textcircled{2} of the first rail 1001, communication between the transport cart 100 and the first collision avoidance control unit 400 through the first control port CP11 is enabled. That is, the transport cart 100 communicates with the first collision avoidance control unit 400 through the first optical cable 201, the first node 351, the first distribution port DP11 and the first control port CP11.

After communication is started, the simulator 700 may control the first collision avoidance control unit 400 to generate an exception signal. When the first collision avoidance control unit 400 generates an exception signal, the transport cart 100 may recognize the exception signal and perform an interlock operation accordingly. The transport cart 100 generates a signal (interlock state signal) indicating success of the interlock and transmits it to the first collision avoidance control unit 400. When the first collision avoidance control unit 400 receives the interlock state signal, the simulator 700 may confirm that the interlock operation of the transport cart 100 is well performed.

The transport cart 100 passes through the first rail 1001 and the connection rail 1009 and moves to the second rail 1002. When the transport cart 100 is at the position \textcircled{3} of the second rail 1002, communication between the transport cart 100 and the first collision avoidance control unit 400 through the first control port CP11 is disabled.

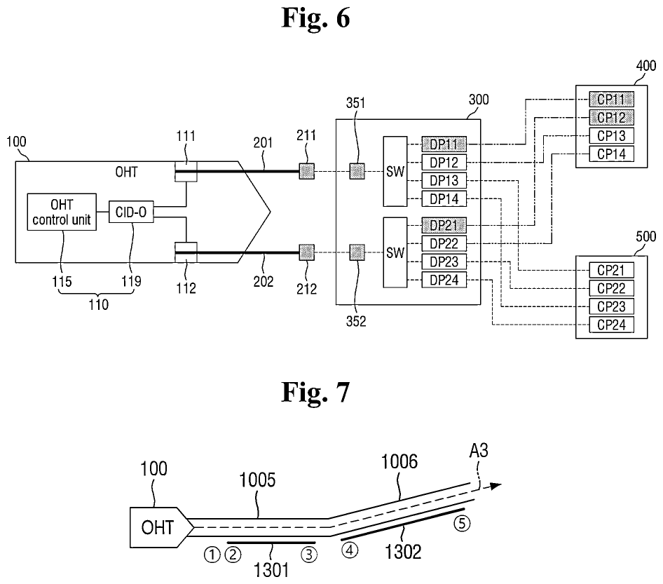

FIG. 5 is a diagram for describing another example of a virtual path. FIG. 6 is a view for describing a control method of a virtual driving system for testing the operation of the transport cart moving along the virtual path shown in FIG. 5.

The virtual path A2 shown in FIG. 5 includes a path at the junction of the rails (i.e., the N-shaped junction). Specifically, the N-shaped junction includes the third rail 1003, the fourth rail 1004 arranged side by side with the third rail 1003, and the connection rail 1008 connecting the third rail 1003 and the fourth rail 1004.

The connection rail 1008 extends from the middle of the third rail 1003 toward the fourth rail 1004. As shown, the second virtual optical cable 1201 is installed on the other side (e.g., the right side) of the third rail 1003 and the connection rail 1008, and the third virtual optical cable 1202 is installed on one side (e.g., left side) of the connection rail 1008 and the fourth rail 1004.

In the virtual path A2 of the transport cart 100, the transport cart 100 moves along the third rail 1003 and moves to the fourth rail 1004 through the connection rail 1008.

Referring to FIGS. 5 and 6, when the virtual driving starts and the transport cart 100 is at the position \textcircled{1} of the third rail 1003, a channel for communication between the transport cart 100 and the first collision avoidance control unit 400 is set. In addition, the simulator 700 controls the signal line distribution unit 300 and the first collision avoidance control unit 400 to set to correspond to the virtual path A2 of FIG. 5.

Specifically, the simulator (see 700 in FIG. 1) allows the signal line distribution unit 300 to connect the first collision avoidance control unit 400 and the first optical cable 201 to each other. Specifically, the first node 351 is connected to the first distribution port DP11 by the first switch 371. Accordingly, the first optical cable 201 is connected to the first control port CP11 of the first collision avoidance control unit 400 through the first node 351 and the first distribution port DP11. In addition, the second node 352 is connected to the second distribution port DP21 by the second switch 372. Accordingly, the second optical cable 202 is connected to the first control port CP12 of the first collision avoidance control unit 400 through the second node 352 and the second distribution port DP21.

In addition, the simulator 700 gives the ID of the second virtual optical cable 1201 of FIG. 5 through the first control port CP12 of the first collision avoidance control unit 400. Accordingly, the transport cart 100 may recognize the ID corresponding to the second virtual optical cable 1201.

When the transport cart 100 is at the position \textcircled{2} of the third rail 1003, communication between the transport cart 100 and the first collision avoidance control unit 400 through the first control port CP12 is enabled. That is, the transport cart 100 communicates with the first collision avoidance control unit 400 through the second optical cable 202, the second node 352, the second distribution port DP21 and the first control port CP12.

After communication is started, the simulator 700 may control the first collision avoidance control unit 400 to generate an exception signal.

When the transport cart 100 is at the position \textcircled{3} of the connection rail 290, the simulator 700 gives the ID of the third virtual optical cable 1202 of FIG. 5 through the first control port CP11 of the first collision avoidance control unit 400. Giving the ID by the simulator 700 may be performed in advance at a previous position (e.g., position \textcircled{1}), rather than when the transport cart 100 is at the position \textcircled{3}. Accordingly, when the transport cart 100 is at the position \textcircled{3} of the connection rail 1008, the transport cart 100 may recognize an ID corresponding to the third virtual optical cable 1202.

In addition, communication between the transport cart 100 and the first collision avoidance control unit 400 through the first control port CP11 is enabled. That is, the transport cart 100 communicates with the first collision avoidance control unit 400 through the first optical cable 201, the first node 351, the first distribution port DP11 and the first control port CP11. After communication is started, the simulator 700 may control the first collision avoidance control unit 400 to generate an exception signal.

When the transport cart 100 is at the position \textcircled{4} of the connection rail 1008, communication between the transport cart 100 and the first collision avoidance control unit 400 through the first control port CP12 is disabled.

The transport cart 100 is moved to the fourth rail 1004 via the connection rail 1008. When the transport cart 100 is at the position \textcircled{5} of the fourth rail 1004, communication between the transport cart 100 and the first collision avoidance control unit 400 through the first control port CP11 is disabled.

In summary, when the transport cart 100 is simulated to communicate with the second virtual optical cable 1201 while moving the third rail 1003 and the connection rail 1008, the transport cart 100 communicates with the first collision avoidance control unit 400 through the first control port CP12.

When the transport cart 100 is simulated to communicate with the third virtual optical cable 1202 while moving the connection rail 1008 and the fourth rail 1004, the transport cart 100 communicates with the first collision avoidance control unit 400 through the first control port CP11.

FIG. 7 is a diagram for describing another example of a virtual path. FIG. 8 is a view for describing a control method of a virtual driving system for testing the operation of the transport cart moving along the virtual path shown in FIG. 7.

The virtual path A3 shown in FIG. 7 includes a path on a ramp. Specifically, the ramp includes a fifth rail 1005 having a first inclination angle, and a sixth rail 1006 connected to the fifth rail 1005 and having a second inclination angle greater than the first inclination angle. FIG. 7 exemplarily illustrates a case where the first inclination angle is 0 degrees and the second inclination angle has an acute angle, but the present invention is not limited thereto. The fourth virtual optical cable 1301 is installed on the other side (e.g., the right side) of the fifth rail 1005, and the fifth virtual optical cable 1302 is installed on the other side (e.g., the right side) of the sixth rail 1006.

In the virtual path A3 of the transport cart 100, the transport cart 100 moves along the fifth rail 1005 and goes up along the sixth rail 1006.

Referring to FIGS. 7 and 8, when the virtual driving starts and the transport cart 100 is at the position \textcircled{1} of the fifth rail 1005, a channel for communication between the transport cart 100 and the second collision avoidance control unit 500 is set. In addition, the simulator (see 700 of FIG. 1) controls the signal line distribution unit 300 and the second collision avoidance control unit 500 to set to correspond to the virtual path A3 of FIG. 7.

Specifically, the simulator 700 allows the signal line distribution unit 300 to connect the second collision avoidance control unit 500 and the second optical cable 202 to each other. More specifically, the second node 352 is connected to the second distribution port DP24 by the second switch 372. Accordingly, the second optical cable 202 is connected to the second control port CP24 of the second collision avoidance control unit 500 through the second node 352 and the second distribution port DP24.

The simulator 700 gives the ID of the fourth virtual optical cable 1301 of FIG. 7 through the second control port CP24 of the second collision avoidance control unit 500. Accordingly, the transport cart 100 recognizes an ID corresponding to the fourth virtual optical cable 1301.

When the transport cart 100 is at the position \textcircled{2} of the fifth rail 1005, communication between the transport cart 100 and the second collision avoidance control unit 500 through the second control port CP24 is enabled. That is, the transport cart 100 communicates with the second collision avoidance control unit 500 through the second optical cable 202, the second node 352, the second distribution port DP24 and the second control port CP24.

After communication is started, the simulator 700 may control the second collision avoidance control unit 500 to generate an exception signal.

When the transport cart 100 is at the position \textcircled{3} of the fifth rail 1005, communication between the transport cart 100 and the second collision avoidance control unit 500 through the second control port CP24 is disabled.

The transport cart 100 is moved to the sixth rail 1006 via the fifth rail 1005. Before the transport cart 100 arrives at the position \textcircled{4} of the sixth rail 1006, the second node 352 is connected to the second distribution port DP23 by the second switch 372. Accordingly, the second optical cable 202 is connected to the second control port CP22 of the second collision avoidance control unit 500 through the second node 352 and the second distribution port DP23.

When the transport cart 100 is at the position \textcircled{4} of the sixth rail 1006, the simulator 700 gives the ID of the fifth virtual optical cable 1302 of FIG. 7 through the second control port CP22 of the second collision avoidance control unit 500. Giving the ID by the simulator 700 may be performed in advance at the previous position (e.g., position \textcircled{1}), rather than when the transport cart 100 is at the position \textcircled{4}. Accordingly, when the transport cart 100 is at the position \textcircled{4}, the transport cart 100 recognizes an ID corresponding to the fifth virtual optical cable 1302.

In addition, communication between the transport cart 100 and the second collision avoidance control unit 500 through the second control port CP22 is enabled. That is, the transport cart 100 communicates with the second collision avoidance control unit 500 through the second optical cable 202, the second node 352, the second distribution port DP23 and the second control port CP22.

When the transport cart 100 is at the position \textcircled{5} of the fifth rail 1005, communication between the transport cart 100 and the second collision avoidance control unit 500 through the second control port CP22 is disabled.

In summary, when the transport cart 100 is simulated to communicate with the fourth virtual optical cable 1301 while moving the fifth rail 1005, the transport cart 100 communicates with the second collision avoidance control unit 500 through the second control port CP24.

When the transport cart 100 is simulated to communicate with the fifth virtual optical cable 1302 while moving the sixth rail 1006, the transport cart 100 communicates with the second collision avoidance control unit 500 through the second control port CP22.

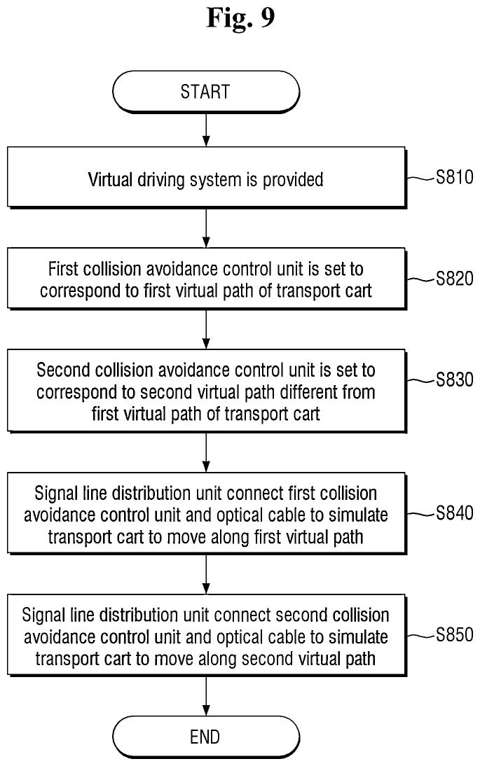

FIG. 9 is a flowchart illustrating a control method of a collision avoidance system according to some embodiments of the present invention.

Referring to FIG. 9, first, a virtual driving system is provided (S810).

For example, the virtual driving system may be the system described with reference to FIGS. 1 to 8. This virtual driving system includes an optical cable 200 installed on a rail, a transport cart 100 that drives in place on the rail and communicates with an optical cable 200, and a signal line distribution unit 300 for selectively connecting any one of a first collision avoidance control unit 400 and a second collision avoidance control unit 500 to the optical cable 200.

Next, the first collision avoidance control unit 400 sets to correspond to the first virtual path of the transport cart 100 (S820). In addition, the second collision avoidance control unit 500 sets to correspond to a second virtual path different from the first virtual path of the transport cart 100 (S830).

Specifically, the first virtual path set by the first collision avoidance control unit 400 may be, for example, the path at the N-shaped junction, described with reference to FIGS. 5 and 6. The N-shaped junction includes a third rail 1003, a fourth rail 1004 arranged side by side with the third rail 1003, and a connection rail 1008 connecting the third rail 1003 and the fourth rail 1004.

The second virtual path set by the second collision avoidance control unit 500 may be, for example, a path on a ramp described with reference to FIGS. 7 and 8. The ramp includes a fifth rail 1005 having a first inclination angle, and a sixth rail 1006 connected to the fifth rail 1005 and having a second inclination angle greater than the first inclination angle.

Then, the signal line distribution unit 300 connects the first collision avoidance control unit 400 and the optical cable 200 to simulate the transport cart 100 to move along the first virtual path (S840). The simulation method may be the same as described with reference to FIGS. 5 and 6.

Then, the signal line distribution unit 300 connects the second collision avoidance control unit 500 and the optical cable 200 to simulate the transport cart 100 to move along the second virtual path (S850). The simulation method may be the same as described with reference to FIGS. 7 and 8.

Although the embodiments of the present invention have been described above with reference to the accompanying drawings, the present invention is not limited to the above embodiments, but may be manufactured in a variety of different forms, and those of ordinary skill in the art to which the present invention pertains can understand that the present invention may be embodied in other specific forms without changing the technical spirit or essential features of the present invention. Therefore, it should be understood that the embodiments described above are illustrative in all respects and not limiting.

What is claimed is:

1. A virtual driving system comprising:
an optical cable installed on a rail;
a transport cart for driving in place on the rail and communicating with the optical cable;
a first collision avoidance control unit set to correspond to a first virtual path of the transport cart;
a second collision avoidance control unit set to correspond to a second virtual path different from the first virtual path of the transport cart;
a signal line distribution unit for selectively connecting any one of the first collision avoidance control unit and the second collision avoidance control unit to the optical cable; and
a simulator for controlling the first collision avoidance control unit, the second collision avoidance control unit, and the signal line distribution unit according to an operation scenario of the transport cart.

2. The system of claim 1, wherein the first virtual path includes a path at a junction of a rail, and the second virtual path includes a path at a ramp.

3. The system of claim 1, wherein the optical cable comprises a first optical cable disposed on one side of the rail and a second optical cable disposed on the other side of the rail.

4. The system of claim 3, wherein the signal line distribution unit comprises,
a first node connected to the first optical cable, a plurality of first distribution ports, and a first switch selectively connecting any one of the plurality of first distribution ports and the first node, and
a second node connected to the second optical cable, a plurality of second distribution ports, and a second switch selectively connecting any one of the plurality of second distribution ports and the second node.

5. The system of claim 4, wherein the first collision avoidance control unit comprises,
a first control port connected to any one of the plurality of first distribution ports, and
a second control port connected to any one of the plurality of second distribution ports.

6. The system of claim 5, wherein the first virtual path includes a first rail, a second rail disposed side by side with the first rail, and a connection rail connecting the first rail and the second rail, a first virtual optical cable extending from the other side of the first rail to the other side of the connection rail installed, and a second virtual optical cable extending from one side of the connection rail to one side of the second rail installed,
wherein, when the transport cart is simulated to communicate with the first virtual optical cable while moving the first rail and the connection rail, the transport cart communicates with the first collision avoidance control unit through the first control port,
wherein, when the transport cart is simulated to communicate with the second virtual optical cable while moving the connection rail and the second rail, the transport cart communicates with the first collision avoidance control unit through the second control port.

7. The system of claim 4, wherein the second collision avoidance control unit comprises,
a third control port connected to any one of the plurality of second distribution ports, and
a fourth control port connected to the other one of the plurality of second distribution ports.

8. The system of claim 7, wherein the second virtual path includes a third rail having a first inclination angle, a fourth rail connected to the third rail and having a second inclination angle greater than the first inclination angle, a third virtual optical cable installed on the other side of the third rail, and a fourth virtual optical cable installed on the other side of the fourth rail,
wherein, when the transport cart is simulated to communicate with the third virtual optical cable while moving the third rail, the transport cart communicates with the second collision avoidance control unit through the third control port,
wherein, when the transport cart is simulated to communicate with the fourth virtual optical cable while moving the fourth rail, the transport cart communicates with the second collision avoidance control unit through the fourth control port.

9. The system of claim 1, wherein the simulator causes the first collision avoidance control unit or the second collision avoidance control unit to generate an exception, and determines whether an interlock is generated in the transport cart due to the generated exception.

10. The system of claim 1, wherein the simulator controls brightness of the optical cable to check an operation of the transport cart according to brightness.

11. A virtual driving system comprising:
a rail;
a first optical cable disposed on one side of the rail and a second optical cable disposed on the other side of the rail;
a transport cart for driving in place on the rail and communicating with at least one of the first optical cable and the second optical cable;
a signal line distribution unit including a first node connected to the first optical cable, a plurality of first distribution ports, a first switch selectively connecting any one of the plurality of first distribution ports to the first node, a second node connected to the second optical cable, a plurality of second distribution ports, and a second switch selectively connecting any one of the plurality of second distribution ports to the second node;
a first collision avoidance control unit including a first control port and a second control port;
a second collision avoidance control unit including a third control port and a fourth control port; and
a simulator for controlling the first collision avoidance control unit, the second collision avoidance control unit, and the signal line distribution unit;
wherein the first control port is connected to any one of the plurality of first distribution ports,
wherein the second control port is connected to any one of the plurality of second distribution ports, the third control port is connected to the other one of the plurality of second distribution ports, and the fourth control port is connected to another one of the plurality of second distribution ports,
wherein the simulator changes a connection relationship between the first switch and the second switch according to an operation scenario of the transport cart.

12. The system of claim 11, wherein the operation scenario of the transport cart includes moving the transport cart along a first virtual path,
wherein the first virtual path includes a first rail, a second rail arranged side by side with the first rail, and a connection rail connecting the first rail and the second rail, a first virtual optical cable extending from the other side of the first rail to the other side of the connection rail installed, and a second virtual optical cable extending from one side of the connection rail to one side of the second rail installed,
wherein, when the transport cart is simulated to communicate with the first virtual optical cable while moving the first rail and the connection rail, the transport cart communicates with the first collision avoidance control unit through the first control port,
wherein, when the transport cart is simulated to communicate with the second virtual optical cable while moving the connection rail and the second rail, the transport cart communicates with the first collision avoidance control unit through the second control port.

13. The system of claim 11, wherein the operation scenario of the transport cart includes moving the transport cart along a second virtual path,
wherein the second virtual path includes a third rail having a first inclination angle, a fourth rail connected to the third rail and having a second inclination angle greater than the first inclination angle, a third virtual optical cable installed on the other side of the third rail, and a fourth virtual optical cable installed on the other side of the fourth rail,
wherein, when the transport cart is simulated to communicate with the third virtual optical cable while moving the third rail, the transport cart communicates with the second collision avoidance control unit through the third control port,
wherein, when the transport cart is simulated to communicate with the fourth virtual optical cable while moving the fourth rail, the transport cart communicates with the second collision avoidance control unit through the fourth control port.

14. The system of claim 11, wherein the simulator causes the first collision avoidance control unit or the second collision avoidance control unit to generate an exception, and determines whether an interlock is generated in the transport cart due to the generated exception.

15. The system of claim 11, wherein the simulator controls brightness of the optical cable to check an operation of the transport cart according to brightness.

16. A method for controlling a virtual driving system comprising:
providing a virtual driving system including an optical cable installed on a rail, a transport cart for driving in place on the rail and communicating with the optical cable, and a signal line distribution unit for selectively connecting any one of a first collision avoidance control unit and a second collision avoidance control unit to the optical cable,
setting the first collision avoidance control unit to correspond to a first virtual path of the transport cart,
setting the second collision avoidance control unit to correspond to a second virtual path different from the first virtual path of the transport cart,
wherein the signal line distribution unit connects the first collision avoidance control unit and the optical cable to simulate the transport cart to move along the first virtual path,
wherein the signal line distribution unit connects the second collision avoidance control unit and the optical cable to simulate moving the transport cart along the second virtual path.

17. The method of claim 16, wherein the first virtual path includes a path at a junction of a rail, and the second virtual path includes a path at a ramp.

18. The method of claim 16, wherein the simulator causes the first collision avoidance control unit or the second collision avoidance control unit to generate an exception, and determines whether an interlock is generated in the transport cart due to the generated exception.
